(19) United States
(12) Patent Application Publication
(10) Pub. No.: US 2023/0192554 A1
(43) Pub. Date: Jun. 22, 2023

(54) INTERMEDIATE COATING FOR HIGH TEMPERATURE ENVIRONMENTS

(71) Applicant: Rolls-Royce Corporation, Indianapolis, IN (US)

(72) Inventor: Taylor K. Blair, Indianapolis, IN (US)

(21) Appl. No.: 17/645,657

(22) Filed: Dec. 22, 2021

(51) Int. Cl. C04B 35/50; C04B 35/622; C04B 41/00; C04B 41/52; C04B 41/50; C04B 41/45; C23C 14/02; C23C 16/02; C23C 16/40; C23C 16/42; C23C 14/06; C23C 14/08

(52) U.S. Cl. CPC C04B 35/50; C04B 35/62222; C04B 41/009; C04B 41/522; C04B 41/5024; C04B 41/4558; C23C 14/024; C23C 16/0272; C23C 16/40; C23C 16/42; C23C 14/0682; C23C 14/08; C04B 2235/428; C04B 2235/3427

(57) ABSTRACT

An article includes a substrate, an intermediate coating on the substrate, and an environmental barrier coating (EBC) on the intermediate coating. The substrate includes a ceramic, ceramic matrix composite (CMC), or superalloy. The EBC includes a rare earth disilicate. When the intermediate coating is at an initial state, such as prior to exposure to an oxidating environment, the intermediate coating includes a bond coat on the substrate and a reactive layer on the bond coat. The bond coat includes silicon, while the reactive layer includes a rare earth monosilicate or rare earth oxide. In response to oxidation of a portion of the silicon of the bond coat to form silicon dioxide, a portion of the rare earth monosilicate or rare earth oxide of the reactive layer is configured to react with at least a portion of the silicon dioxide to form a converted layer that includes a rare earth disilicate.

### TECHNICAL FIELD

The disclosure relates to coatings for materials in high temperature oxidative environments.

### BACKGROUND

Ceramic or ceramic matrix composite (CMC) materials may be useful in a variety of contexts where mechanical and thermal properties are important. Ceramic or CMC materials may be resistant to high temperatures, but some ceramic or CMC materials may react with some elements and compounds present in the operating environment of high temperature mechanical systems, such as water vapor. Reaction with water vapor may result in the recession of the ceramic or CMC material. These reactions may damage the ceramic or CMC material and reduce mechanical properties of the ceramic or CMC material, which may reduce the useful lifetime of the component. Thus, in some examples, a ceramic or CMC material may be coated with an environmental barrier coating (EBC), which may reduce exposure of the substrate to elements and compounds present in the operating environment of high temperature mechanical systems.

### SUMMARY

The disclosure describes an intermediate coating that may, e.g., reduce spallation or delamination of an EBC from a substrate, such as a ceramic, ceramic matrix composite (CMC), or superalloy. The intermediate coating includes a bond coat that includes silicon. Oxidating species may infiltrate the EBC into the bond coat and react with the bond coat to produce silicon dioxide in a thermally grown oxide (TGO) layer. The intermediate coating further includes a reactive layer on the bond coat to reduce a thickness of the TGO layer. The reactive layer includes a rare earth monosilicate or rare earth oxide that reacts with at least a portion of the silicon dioxide to from a converted layer of a rare earth disilicate. As a result, the TGO layer may be relatively thin compared to coating systems that do not include a reactive layer between a bond coat and an EBC.

In some examples, the disclosure describes an article that includes a substrate, an intermediate coating on the substrate, and an environmental barrier coating (EBC) on the intermediate coating. The substrate includes at least one of a ceramic, a ceramic matrix composite (CMC), or a superalloy. The EBC includes a rare earth disilicate, such as ytterbium disilicate. When the intermediate coating is at an initial state, the intermediate coating includes a bond coat on the substrate and a reactive layer on the bond coat. The bond coat includes silicon, while the reactive layer includes a rare earth monosilicate or rare earth oxide, such as ytterbium monosilicate or ytterbium oxide. In response to oxidation of at least a portion of the silicon of the bond coat to form silicon dioxide, at least a portion of the rare earth monosilicate or rare earth oxide of the reactive layer is configured to react with at least a portion of the silicon dioxide to form a converted layer that includes a rare earth disilicate.

In some examples, the disclosure describes a method of forming an article that includes forming an intermediate coating on a substrate. The substrate includes at least one of a ceramic, a ceramic matrix composite (CMC), or a superalloy. The intermediate coating includes a bond coat on the substrate and a reactive layer on the bond coat. The bond coat includes silicon, while the reactive layer includes a rare earth monosilicate or rare earth oxide. The method includes forming an environmental barrier coating (EBC) on the reactive layer. The EBC includes a rare earth disilicate. In response to oxidation of at least a portion of the silicon of the bond coat to form silicon dioxide, at least a portion of the rare earth monosilicate or rare earth oxide of the reactive layer is configured to react with at least a portion of the silicon dioxide to form a converted layer comprising a rare earth disilicate.

In some examples, the disclosure describes a method of operating an article that includes exposing the article to a high temperature oxidative environment. The article includes a substrate, an intermediate coating on the substrate, and an environmental barrier coating (EBC) on the intermediate coating. The substrate includes at least one of a ceramic, a ceramic matrix composite (CMC), or a superalloy. The EBC includes a rare earth disilicate, such as ytterbium disilicate. When the intermediate coating is at an initial state, the intermediate coating includes a bond coat on the substrate and a reactive layer on the bond coat. The bond coat includes silicon, while the reactive layer includes a rare earth monosilicate or rare earth oxide, such as ytterbium monosilicate or ytterbium oxide. In response to oxidation of at least a portion of the silicon of the bond coat to form silicon dioxide, at least a portion of the rare earth monosilicate or rare earth oxide of the reactive layer reacts with at least a portion of the silicon dioxide to form a converted layer that includes a rare earth disilicate.

The details of one or more examples are set forth in the accompanying drawings and the description below. Other features, objects, and advantages will be apparent from the description and drawings, and from the claims.

### BRIEF DESCRIPTION OF DRAWINGS

FIG. 1A is a conceptual diagram illustrating a cross-sectional view of an example of an article that includes an intermediate coating at an initial state.

FIG. 1B is a conceptual diagram illustrating a cross-sectional view of an example of the article of FIG. 1A that includes the intermediate coating at a partially expended state.

FIG. 1C is a conceptual diagram illustrating a cross-sectional view of an example of the article of FIG. 1A that includes the intermediate coating at a fully expended state.

FIG. 2 is a conceptual diagram illustrating a cross-sectional view of an example of an article used in a high-temperature mechanical system that includes an additional coating.

FIG. 3 is a flow diagram illustrating an example technique for forming an intermediate coating on ceramic matric composite (CMC) substrate.

FIG. 4 is a temperature-phase diagram of ytterbium oxide and silicon dioxide.

FIG. 5 is a micrograph of an article that includes an ytterbium monosilicate reactive layer in between an ytterbium disilicate EBC and a CMC substrate.

### DETAILED DESCRIPTION

The disclosure describes an intermediate coating that may reduce spallation or delamination of an EBC from a ceramic or CMC substrate. An EBC may be adhered to a ceramic or CMC substrate by a bond coat. The bond coat may act as an adhesive for the EBC and a passive barrier layer for oxidative species, such as oxygen, water vapor, or the like. The EBC may provide oxidation and water vapor resistance to both the bond coat and the substrate. However, the EBC may have microstructural characteristics, such as pores, cracks, grains, and the like, that allow migration of oxidative species and lower the oxidation resistance of the EBC. For example, an EBC may have pores formed during deposition or component operation that allow oxidative species to contact the bond coat and form a thermally grown oxide (TGO) layer. However, thinner TGO thickness is generally desirable and may improve the life of the coating.

In some examples, the oxidation resistance of the EBC may be improved by increasing the density and/or thickness of the EBC to reduce the diffusion and migration of the oxidative species through the EBC. For example, an EBC having a higher density at a particular thickness may increase the oxidation resistance of the EBC; likewise, an EBC having a greater thickness at a particular density may increase the oxidation resistance of the EBC. However, as density and/or thickness of the EBC increases, the compliance of the EBC decreases, which may increase the likelihood of the EBC to develop through-thickness cracks or delaminate from the bond coat.

According to principles of the disclosure, a coating system may have improved oxidation resistance with a reduced TGO layer and/or likelihood of developing through-thickness cracks. The coating system includes an intermediate coating between the EBC and the ceramic or CMC substrate. The intermediate coating includes a bond coat that includes silicon and a reactive layer on the bond coat that reduces a thickness and/or rate of formation of the TGO layer from the bond coat. The reactive layer includes a rare earth monosilicate and/or rare earth oxide, or rare earth monosilicate rich and/or rare earth monosilicate rich phase that reacts with at least a portion of the silicon dioxide to from a converted layer of a rare earth disilicate or rare earth disilicate rich phase. This equilibrium phase may be compatible with the EBC, and in some examples, may further contribute to resistance to oxidative species. As a result, the TGO layer may be relatively thin compared to coating systems that do not include a reactive layer between a bond coat and an EBC.

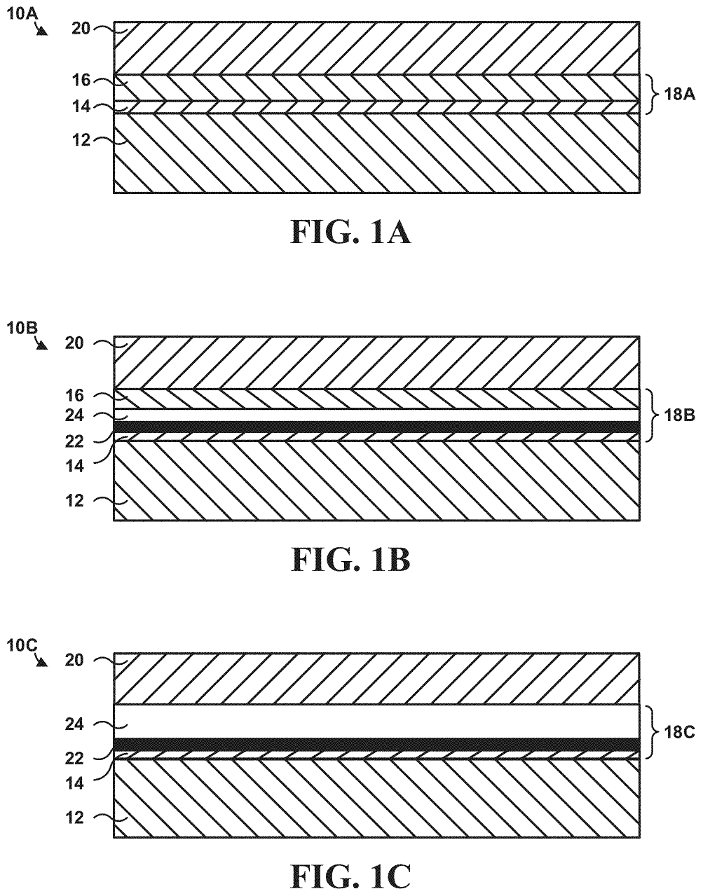

Intermediate coatings described herein may be used in a variety of mechanical systems, including high-temperature mechanical systems exposed to high-temperature oxidative environments. FIG. 1A illustrates a cross-sectional view of an example of an article 10A used in a high-temperature mechanical system. Article 10 may be a component of a high-temperature mechanical system. For example, article 10 may be a blade track, a blade shroud, an airfoil, a blade, a vane, a combustion chamber liner, or the like, of a gas turbine engine. Article 10 includes a substrate 12, an intermediate coating 18A on substrate 12, and an environmental barrier coating (EBC) 20 on intermediate coating 18A.

Substrate 12 may include any substrate configured for operation in a high-temperature oxidative environment. In some examples, substrate 12 includes a ceramic matrix composite (CMC) that includes a matrix material and a reinforcement material. The matrix material includes a ceramic material, such as, for example, silicon carbide, silicon nitride, alumina, aluminosilicate, silica, or the like. The CMC further includes a continuous or discontinuous reinforcement material. For example, the reinforcement material may include discontinuous whiskers, platelets, or particulates. As other examples, the reinforcement material may include a continuous monofilament or multifilament weave. In some examples, the composition of the reinforcement material is the same as the composition of the matrix material. For example, a matrix material comprising silicon carbide may surround a reinforcement material comprising silicon carbide whiskers. In other examples, the reinforcement material includes a different composition than the composition of the matrix material, such as aluminosilicate fibers in an alumina matrix, or the like. One composition of a substrate 12 that includes a CMC includes a reinforcement material comprising silicon carbide continuous fibers embedded in a matrix material comprising silicon carbide. In some examples, substrate 12 may include a SiC—SiC CMC, in which a fibrous preform including SiC fibers is impregnated with SiC particles from a slurry, then melt infiltrated with silicon metal or a silicon alloy to form the melt-infiltrated SiC—SiC CMC.

In addition to CMC substrates, substrate 12 may include other materials, such as ceramics or superalloys. In some examples in which substrate 12 includes a ceramic, the ceramic may be substantially homogeneous. In some examples, a substrate 12 that includes a ceramic includes, for example, a silicon-containing ceramic, such as silica (SiO₂), silicon carbide (SiC) or silicon nitride (Si₃N₄); alumina (Al₂O₃); aluminosilicate; or the like. In other examples, substrate 12 includes a metal alloy that includes silicon, such as a molybdenum-silicon alloy (e.g., MoSi₂) or a niobium-silicon alloy (e.g., NbSi₂). In examples in which substrate 12 includes a superalloy, substrate 12 may include an alloy based on Ni, Co, Ni/Fe, Ti, or the like. Substrate 12 may include other additive elements to alter mechanical properties of substrate 12, such as toughness, hardness, temperature stability, corrosion resistance, oxidation resistance, and the like, as is well known in the art. In examples in which substrate 12 is a superalloy, substrate 12 may include one or more additional layers between substrate 12 and bond coat 14 to create a CTE gradient between substrate 12 and bond coat 14, such as to minimize CTE difference between adjacent layers. Any useful superalloy may be utilized in substrate 12, including, for example, those available from Martin-Marietta Corp., Bethesda, Md., under the trade designation MAR-M247; those available from Cannon-Muskegon Corp., Muskegon, Mich., under the trade designations CMSX-4 and CMSX-10; and the like.

Article 10 further includes an environmental barrier coating (EBC) 20 overlying substrate 12 on intermediate coating 18A. In the example illustrated in FIG. 1A, EBC 20 includes a single layer; however, in other examples, EBC 20 may include more than one EBC layer. EBC 20 may include a rare earth disilicate (RE₂Si₂O₇, where RE stands for “rare earth”). For example, EBC 20 may have a phase composition that is at least about 50% by volume of the rare earth disilicate, such as greater than about 80% by volume. The rare earth disilicate may reduce or substantially prevent attack of substrate 12 and/or intermediate coating 18A by chemical species present in the environment in which article 10 is utilized, e.g., in the intake gas or exhaust gas of a gas turbine engine. Rare earth elements that may be used in the rare earth disilicates include, but are not limited to, La, Pr, Nd, Pm, Sm, Eu, Gd, Tb, Dy, Ho, Er, Tm, Yb, Lu, Y, Sc, and the like. In some examples, the rare earth disilicate may have a coefficient of thermal expansion (CTE) that is close to substrate 12 and/or a portion of intermediate coating 18A. For example, in examples where EBC 20 includes ytterbium disilicate (Yb₂Si₂O₇), a portion (e.g., bond coat 14) of intermediate coating 18A includes silicon (Si) metal, and substrate 12 includes silicon carbide (SiC), ytterbium disilicate may have a CTE of about 4.7×10⁻⁶° C.⁻¹, while silicon and silicon carbide may each have a CTE of about 4.5×10⁻⁶° C.⁻¹. In some examples, EBC 20 may additionally include free silica (e.g., silica that has not reacted with rare earth oxide to form rare earth disilicate), free rare earth oxide (e.g., rare earth oxide that has not reacted with silica to form rare earth disilicate), rare earth monosilicate (RESiO₅, where RE stands for “rare earth”), or combinations thereof.

Intermediate coating 18A may be configured to improve adhesion between substrate 12 and EBC 20 with reduced cracking, spallation, and/or delamination. Intermediate coating 18A includes a bond coat 14 on substrate 12. As shown in FIG. 1, article 10 includes bond coat 14 on substrate 12. In the example illustrated in FIG. 1A, bond coat 14 includes a single layer; however, in other examples, bond coat 14 may include more than one layer.

Bond coat 14 may improve adhesion between substrate 12 and EBC 20, and may act as a protective layer that decreases migration of an oxidizing agent into substrate 12 by reacting with an oxidizing species to form a protective thermally grown oxide (TGO) layer. Bond coat 14 may include any useful material that improves adhesion between substrate 12 and an overlying layer. For example, in examples in which substrate 12 is a ceramic or CMC, bond coat 14 may include silicon metal and, optionally, one or more additional elements.

In examples in which substrate 12 is a ceramic or CMC, bond coat 14 may include a silicon-based bond coat, and may include silicon metal (e.g., elemental silicon; Si), a silicon-containing alloy, a silicon-containing ceramic, or another silicon-containing compound in which the silicon may oxidize to form silicon dioxide. In some examples, the presence of Si in bond coat 14 may promote adherence between bond coat 14 and substrate 12 and between bond coat 14 and multilayer EBC 20, such as, for example, when substrate 12, multilayer EBC 20, or both, includes silicon metal or a silicon-containing alloy or compound. A bond coat 14 that is silicon-based may optionally include at least one additive. The optional at least one additive may include, for example, at least one of SiC, an oxidation enhancer, a transition metal carbide, a transition metal boride, or a transition metal nitride. SiC may affect the properties of bond coat 14. For example, SiC particles may modify oxidation resistance of bond coat 14, modify chemical resistance of bond coat 14, influence the CTE of bond coat 14, or the like. In some examples, bond coat 14 may include between about 1 vol. % and about 40 vol. % SiC, such as between about 1 vol. % and about 20 vol. % SiC, or between about 5 vol. % and about 40 vol. % SiC, or between about 5 vol. % and about 20 vol. % SiC. The composition of bond coat 14 may be selected based on a number of considerations, including the chemical composition and phase constitution of substrate 12 and EBC 20.

In the example of FIG. 1A, intermediate coating 18A represents an initial state. When intermediate coating 18A is at an initial state, intermediate coating 18A includes bond coat 14 on substrate 12 and a reactive layer 16 on bond coat 14. In the example illustrated in FIG. 1A, reactive layer 16 includes a single layer; however, in other examples, reactive layer 16 may include more than one layer. As mentioned above, bond coat 14 may act as a protective layer that decreases migration of an oxidizing agent into substrate 12. Bond coat 14 may form a protective thermally grown oxide (TGO) layer with the oxidizing species. However, it is generally desirable to keep TGO thinner for improved coating life. For example, a relatively thick TGO layer may increase a likelihood of cracking, spallation, delamination, or other defect due to CTE mismatch.

To limit formation of the TGO layer during operation of article 10A in a high temperature environment due to migration and reaction of oxidating species, intermediate coating 18A includes reactive layer 16 on bond coat 14. Reactive layer 16 includes a rare earth monosilicate (RE₂SiO₅, where RE stands for “rare earth”) or rare earth oxide (RE₂O₃). Reactive layer 16 may have a high relative (e.g., compared to EBC 20) or absolute phase composition of rare earth monosilicate or rare earth oxide. As one example, reactive layer 16 may have a phase composition that is at least about 40% by volume of the rare earth monosilicate or rare earth oxide, such as greater than about 80% by volume, and in some examples, may have a remainder of rare earth disilicate. As another example, reactive layer 16 may initially (e.g., prior to exposure of bond coat 14 to an oxidizing species) have a phase composition of rare earth monosilicate that is greater than a phase composition of rare earth monosilicate of EBC 20, such as greater than at least 20% by volume. Rare earth elements that may be used in the rare earth monosilicates or rare earth oxides include, but are not limited to, La, Pr, Nd, Pm, Sm, Eu, Gd, Tb, Dy, Ho, Er, Tm, Yb, Lu, Y, Sc, and the like. In some examples, the rare earth monosilicate includes ytterbium monosilicate and/or the rare earth oxide includes ytterbium oxide.

Reactive layer 16 may reduce a thickness of a TGO layer formed on bond coat 14 by converting a portion of the TGO layer to an overlying converted layer that includes a rare earth disilicate. FIG. 1B is a conceptual diagram illustrating a cross-sectional view of an example of the article of FIG. 1A that includes an intermediate coating 18B at a partially expended state. When intermediate coating 18B is at an operating state, such as the partially expended state illustrated in FIG. 1B, intermediate coating 18B includes bond coat 14, a thermally-grown oxide (TGO) layer 22 on bond coat 14, and a converted layer 24 on TGO layer 22.

TGO layer 22 may result from partial oxidation of the silicon of bond coat 14, while converted layer 24 may result from an intermediate phase formed between the rare earth monosilicate or rare earth oxide of reactive layer 16 and silicon dioxide of TGO layer 22. Without being limited to any particular theory, at least a portion of the silicon of bond coat 14 may react with oxidating species to form silicon dioxide in a thermally-grown oxide (TGO) layer 22. Without reactive layer 16, TGO layer 22 may continue to grow at a relatively high rate until the silicon of bond layer 14 has fully oxidized. However, at least a portion of the rare earth monosilicate or rare earth oxide of reactive layer 16 is configured to react with at least a portion of the silicon dioxide of TGO layer 22 at an interface between TGO layer 22 and reactive layer 16 to form a converted layer 24 of a rare earth disilicate. For example, converted layer 24 may have a phase composition that is at least about 40% by volume of the rare earth disilicate, such as greater than about 90% by volume, and may increase as a phase of the rare earth monosilicate or rare earth oxide and a portion of TGO layer 22 is converted to rare earth disilicate. As a result, TGO layer 22 may be relatively thin compared to a TGO layer that is not adjacent to reactive layer 16. This converted layer 24 may be more compatible with EBC 20 than TGO layer 22, including having a more similar CTE.

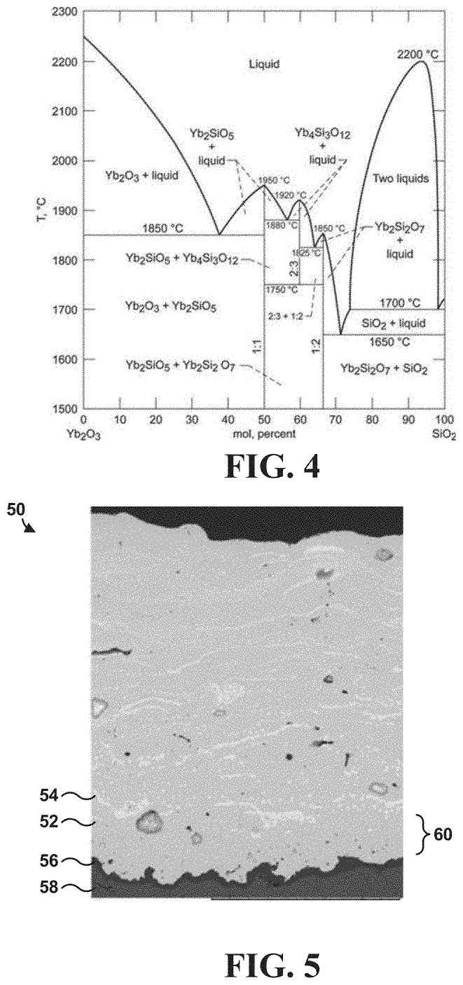

As one example, FIG. 4 is a temperature-phase diagram of ytterbium oxide and silicon dioxide, including phases of ytterbium monosilicate (Yb₂SiO₅) and ytterbium disilicate (Yb₂Si₂O₇). As illustrated in FIG. 4, as silicon dioxide from TGO layer 22 migrates into reactive layer 16 of ytterbium monosilicate and/or ytterbium oxide, at least a portion of the ytterbium monosilicate and/or ytterbium oxide may convert to ytterbium disilicate and ytterbium monosilicate and, eventually, ytterbium disilicate, such as near an interface between TGO layer 22 and converted layer 24.

FIG. 5 is a micrograph of an article 50 that includes an overlying layer 52 that includes a phase of ytterbium monosilicate. Article 50 includes a bond coat 58 that includes silicon metal, a TGO layer 56 that includes silicon dioxide formed from the silicon metal of bond coat 58, and an overlying layer 52 on TGO layer 56. Overlying layer 52 includes a continuous phase of ytterbium disilicate and a dispersed phase of ytterbium monosilicate, and may function as both an environmental barrier coating and a reactive layer. Overlying layer 52 includes a portion 60 adjacent to TGO layer 56 that is substantially depleted of ytterbium monosilicate, as the ytterbium monosilicate has reacted with silicon dioxide from TGO layer 56 to form ytterbium disilicate.

Referring back to FIG. 1B, in addition to forming a thinner TGO layer 22 and/or forming a TGO layer 22 at a slower rate, converted layer 24 may be chemically compatible with EBC 20 and/or may have a similar CTE as EBC 20. For example, both EBC 20 and converted layer 24 may include a rare earth disilicate, and in some examples, may include the same rare earth disilicate. As a result, converted layer 24 may not react with EBC 20 or may not generate substantial thermal stresses on EBC 20 from CTE mismatch. In some examples, such as illustrated in FIG. 1C below, reactive layer 16 may be completely used up, such that converted layer 24 may eventually form an interface with EBC 20.

In some examples, the rare earth disilicate of converted layer 24 may further contribute to resistance to oxidative species, such as water vapor or CMAS. For example, as mentioned above with respect to EBC 20, rare earth disilicates, such as ytterbium disilicate, may reduce or substantially prevent attack of substrate 12 and/or intermediate coating 18A by oxidative species present in the environment in which article 10A is utilized. As a result, as converted layer 24 is formed, resistance of article 10 to oxidative species may increase.

While EBC 20, reactive layer 16, and converted layer 24 have been described as separate layers, in some examples, EBC 20, reactive layer 16, and converted layer 24 may be present as a continuous layer or interconnected layers having different phase compositions of rare earth disilicate and rare earth monosilicate and/or rare earth oxide. For example, reactive layer 16 may be differentiated from EBC 20 or converted layer 24 by including a relatively high phase of rare earth monosilicate or rare earth oxide, such as greater than about 40% by volume, than the phase of rare earth monosilicate or rare earth oxide in EBC 20 or converted layer 24. As a phase of rare earth monosilicate and/or rare earth oxide in a portion of reactive layer 16 is converted to rare earth disilicate, the portion of reactive layer 16 may become converted layer 24 having a relatively high phase of rare earth disilicate, such as greater than about 40% by volume. In other words, rather than representing distinct layers, EBC 20 and converted layer 24 may be portions of an overlying coating on bond coat 14 that have a relatively high phase composition of a phase of rare earth disilicate, while reactive layer 16 may be one or more portions of the overlying coating on bond coat 14 that have relatively high phase composition of a rare earth monosilicate and/or rare earth oxide.

When intermediate coating 18A is at an initial state, such as illustrated in article 10A of FIG. 1A, intermediate coating 18A includes bond coat 14 at an initial thickness and reactive layer 16 at an initial thickness and/or initial phase composition. When intermediate coating 18B is at an operating state, such as the partially expended state illustrated in FIG. 1B, intermediate coating 18B includes bond coat 14 at a working thickness that is less than the initial thickness due to oxidation of at least a portion of the silicon of bond coat 14 to silicon dioxide in TGO layer 22. Reactive layer 16 includes a working thickness that is less than the initial thickness and/or a working phase composition of rare earth monosilicate or rare earth oxide that is less than the initial phase composition of rare earth monosilicate or rare earth oxide due to conversion of the rare earth monosilicate or rare earth oxide of reactive layer 16 to the rare earth disilicate of converted layer 24.

Referring back to FIG. 1A, reactive layer 16 may have a relatively low thickness, such that reactive layer 16 may not generate substantial thermally-induced stresses on adjacent layers, such as EBC 20 or converted layer 24. In some examples, reactive layer 16 may have an initial thickness between about 10 microns and about 50 microns. In some examples, the initial thickness of reactive layer 16 may be configured to provide a desired amount of service life of article 10A. For example, reactive layer 16 may continue to form converted layer 24 until reactive layer 16 is either used up or made ineffective, such as by formation of a substantially thick TGO layer 22.

FIG. 1C is a conceptual diagram illustrating a cross-sectional view of an example of an article 18C that includes an intermediate coating 18C at a fully expended state. As illustrated in FIG. 1C, intermediate coating 18C no longer includes reactive layer 16; instead, intermediate coating 18C only includes bond coat 14 having a lower thickness than bond coat 14 of FIG. 1B, TGO layer 22 having a greater thickness than TGO layer 22 of FIG. 1B, and converted layer 24 having a greater thickness than converted layer 24 of FIG. 1B. Continued operation of article 18C may result in TGO layer 22 forming at a faster rate than formation of TGO layer 22 prior to full expenditure of reactive layer 16. In some examples, a buffer amount (e.g., greater than about 20%) may remain at a projected end of an operating life of intermediate coating 18.

An amount of rare earth monosilicate or rare earth oxide in reactive layer 16 may be configured to reduce or slow formation of TGO layer 22. A higher amount of rare earth monosilicate or rare earth oxide in reactive layer 16 may correspond to reduced or slowed formation of GTO layer 22. The amount of rare earth monosilicate or rare earth oxide may be controlled by a thickness of reactive layer 16 and/or a phase composition of rare earth monosilicate or rare earth oxide in reactive layer 16.

In some examples, an initial thickness of reactive layer 16 may be configured based on a desired service life of article 10A and/or desired resulting thickness of TGO layer 22. As one example, for a particular oxidative environment (e.g., concentration of oxidative species and/or temperature), the rare earth monosilicate or rare earth oxide of reactive layer 16 may be configured to form the rare earth disilicate of converted layer 24 at a particular rate or pattern (e.g., varying rate). As a result, the initial thickness of reactive layer 16 may be configured such that reactive layer 16 is present for a desired length of protection of article 10A, such as a service life of article 10A. As another example, for a particular desired thickness of TGO layer 22 (e.g., a thickness of TGO layer 22 at which continued operation of article 10A may not be recommended), the rare earth monosilicate or rare earth oxide of reactive layer 16 may be configured to form the rare earth disilicate of converted layer 24 at a rate or pattern that corresponds to a rate or pattern of formation of TGO layer 22 from bond coat 14. The rate of consumption of TGO layer 22 may be lower than a rate of formation of TGO layer 22, such that TGO layer 22 may continue to build up, albeit at a slower rate. As a result, the initial thickness of reactive layer 16 may be configured such that reactive layer 16 is present until formation of TGO layer 22 to the desired thickness.

In some examples, an initial phase composition of reactive layer 16 may be configured based on a desired service life of article 10A. For example, for a particular oxidative environment (e.g., concentration of oxidative species and/or temperature), the phase composition of the rare earth monosilicate or rare earth oxide of reactive layer 16 may be configured to form a phase composition of the rare earth disilicate of converted layer 24 at a particular rate or pattern (e.g., varying rate), such that the rare earth monosilicate or rare earth oxide reduces a thickness and/or rate of growth of TGO layer 22 for the desired service life of article 10A compared to growth of TGO layer 22 without reactive layer 16. As such, the initial phase composition of reactive layer 16 may be configured such that reactive layer 16 is present for a desired length of protection of article 10A, such as a service life of article 10A.

Referring collectively to FIGS. 1A-C, article 10A may be operated by exposing article 10A to a high temperature oxidative environment. Reactive layer 16 may have an initial thickness prior to exposure to the high temperature oxidative environment. The high temperature oxidative environment may include oxidating species that penetrate EBC 20 and reactive layer 16 to oxidize at least a portion of the silicon of bond coat 14 to form silicon dioxide in TGO layer 22. In response to oxidation of at least a portion of the silicon of bond coat 14, at least a portion of the rare earth monosilicate or rare earth oxide of reactive layer 16 reacts with at least a portion of the silicon dioxide to form converted layer 24 that includes a rare earth disilicate. Article 10A may continue to be exposed to the high temperature oxidative environment until an operating thickness of the reactive layer is less than a particular threshold, such as about 80% of the initial thickness of reactive layer 16. As a result of formation of converted layer 24, TGO layer 22 may form at a lower rate than a TGO layer that is not adjacent to reactive layer 16.

Coating systems described herein that include a reactive layer may be more robust than coating systems that do not include the reactive layer. As one example, articles that include the reactive layer may form a thinner TGO layer and/or may form a TGO layer at a lower rate, thereby reducing a likelihood of damage to bond coat 14 or EBC 20 due to thermal stresses and/or increasing a service life of the article. As another example, articles that include the reactive layer may form a converted layer that, in addition to limiting formation of the TGO layer, may be compatible with EBC 20 and/or increase resistance to oxidative species. In these various ways, articles described herein may have reduced damage and/or extended life when operated in high-temperature oxidative environments.

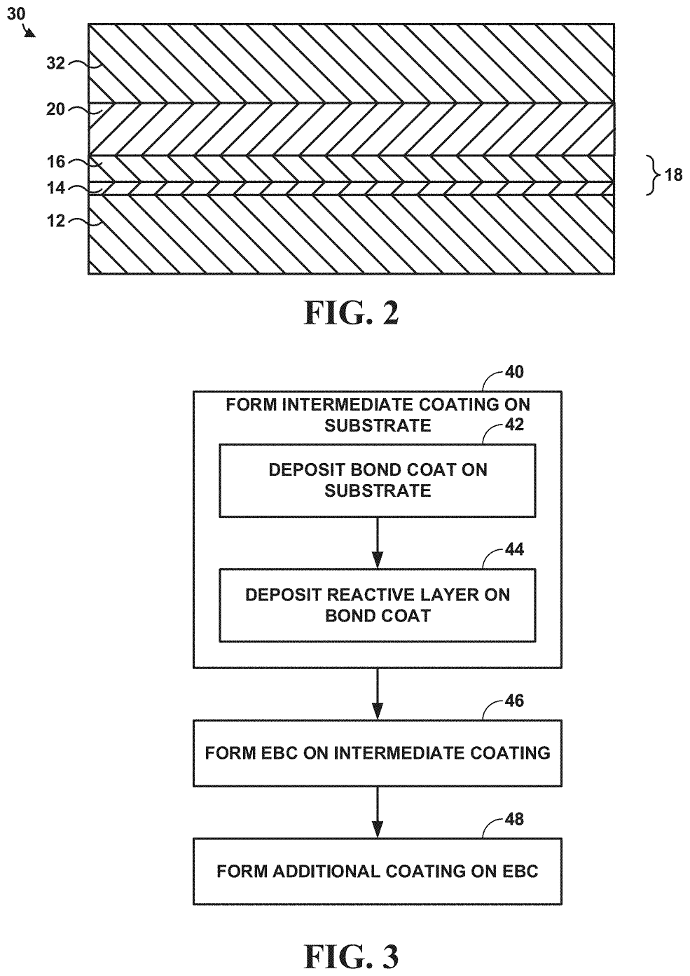

In some examples, a coating system may include additional layers on EBC 20. FIG. 2 shows a cross-sectional view of an example of an article 30 used in a high-temperature mechanical system that includes an additional coating 32. Article 30 includes substrate 12, intermediate coating 18 on substrate 12, including bond coat 14 on substrate 12 and reactive layer 16 on bond coat 14, EBC 20 on intermediate coating 18, and additional coating 32 on EBC 30.

Additional coating 32 may provide one or more function to multilayer EBC 20. For example, additional coating 32 may include a thermal barrier coating (TBC), a CMAS-resistant coating, an abradable coating, an erosion resistance coating, or the like.

A TBC may have a low thermal conductivity (e.g., both an intrinsic thermal conductivity of the material(s) that forms the TBC and an effective thermal conductivity of the TBC as constructed) to provide thermal insulation to substrate 12, bond coat 14, and/or multilayer EBC 50. In some examples, a TBC may include a zirconia- or hafnia-based material, which may be stabilized or partially stabilized with one or more oxides. In some examples, the inclusion of rare-earth oxides such as ytterbia, samaria, lutetia, scandia, ceria, gadolinia, neodymia, europia, yttria-stabilized zirconia (YSZ), zirconia stabilized by a single or multiple rare-earth oxides, hafnia stabilized by a single or multiple rare-earth oxides, zirconia-rare-earth oxide compounds, such as RE₂Zr₂O₇ (where RE is a rare-earth element), hafnia-rare-earth oxide compounds, such as RE₂Hf₂O₇ (where RE is a rare-earth element), and the like may help decrease the thermal conductivity (by conduction) of the TBC. In some examples, a TBC may include a base oxide including zirconia or hafnia, a first rare earth oxide including ytterbia, a second rare earth oxide including samaria, and a third rare earth oxide including at least one of lutetia, scandia, ceria, neodymia, europia, or gadolinia. A TBC may include porosity, such as a columnar or microporous microstructure, which may contribute to relatively low thermal conductivity of the TBC.

A CMAS-resistant coating may include an element or compound that reacts with CMAS to form a solid or a highly viscous reaction product (i.e., a reaction product that is a solid or highly viscous at the temperatures experienced by article 30), or reduces a reaction rate of the CMAS-resistant coating with CMAS or a migration rate of CMAS into the CMAS-resistant coating. In some examples, the CMAS-resistant coating includes Al₂O₃ and at least one rare-earth oxide, such as, for example, an oxide of at least one of Sc, Y, La, Ce, Pr, Nd, Pm, Sm, Eu, Gd, Tb, Dy, Ho, Er, Tm, Yb, Lu, or combinations thereof. The combination of Al₂O₃ and at least one rare-earth oxide may allow tailoring of one or more properties of the CMAS-resistant coating, such as, for example, the chemical reactivity of the CMAS-resistant coating with CMAS, the viscosity of the reaction products, the CTE of the CMAS-resistant coating, the chemical compatibility of the CMAS-resistant coating with bond coat 14, reactive layer 16, or the like.

In some examples, additional coating 32 may include an abradable coating. The abradable coating may be selected to protect multilayer EBC 30 from physical damage, such as impact against other components. An abradable coating may be configured to be abraded, e.g., by a blade of a gas turbine engine, in order to form a relatively tight seal between article 30 and another component, such as, for example, a blade of a gas turbine engine. Abradability may include a disposition to break into relatively small pieces when exposed to a sufficient physical force. Abradability may be influenced by the material characteristics of the material(s) in the abradable coating, such as fracture toughness and fracture mechanism (e.g., brittle fracture), as well as the porosity of the abradable coating. In examples in which additional coating 32 includes an abradable costing, additional coating 32 may exhibit thermal shock resistance and high-temperature capability.

The abradable coating may include any suitable material. For example, the abradable coating may include at least one of a rare-earth oxide, a rare-earth silicate, an aluminosilicate, or an alkaline earth aluminosilicate. In some examples, as described above, additional coating 32 including an abradable coating includes at least one rare-earth disilicate, mullite, BSAS, BAS, SAS, at least one rare earth oxide, at least one rare earth monosilicate, or combinations thereof. Additionally, or alternatively, additional coating 32 including an abradable coating may include any of the compositions described herein with respect to the EBC. In such examples, a porosity of the abradable coating may be greater than a porosity of EBC 20.

FIG. 3 is a flow diagram illustrating an example method for forming a multilayer EBC on a substrate. The method of FIG. 3 will be described with concurrent reference to article 10A of FIG. 1A and article 30 of FIG. 2; however, it will be understood that the method of FIG. 3 may be used to produce other articles, and that the articles of FIGS. 1-2 may be produced by other methods.

As shown in FIG. 1A, an intermediate coating 18A may be formed on a substrate 12, such as a ceramic matrix composite (CMC) substrate (40). To form intermediate coating 18A, the method may include depositing bond coat 14 on substrate 12 (42) and depositing reactive layer 16 on bond coat 14 (44). In some examples, bond coat 14 may be deposited on a surface of substrate 12, and/or reactive layer 16 may be deposited on a surface of bond coat 14, using thermal spraying; a vapor phase deposition technique such as PVD, EB-PVD, DVD, or CVD; slurry deposition, or other suitable technique.

As shown in FIG. 1A, an environmental barrier coating (EBC) 20 may be formed on intermediate coating 18A (46). Multilayer environmental barrier coating 20 may be deposited by any one or more suitable coating fabrication technique, including, for example, thermal spraying; a vapor phase deposition technique such as, physical vapor deposition (PVD), electron beam PVD (EB-PVD, directed vapor deposition (DVD), or chemical vapor deposition (CVD); a slurry process; or the like. As shown in FIG. 2, additional layers may optionally be formed on EBC 20, such as layer 32 of article 30 (48). For example, additional coating 52 may be deposited on multilayer EBC 20 using thermal spraying; a vapor phase deposition technique such as PVD, EB-PVD, DVD, or CVD; slurry deposition, or other suitable technique.

In some examples, rather than forming reactive layer 16 and EBC 20 during separate steps, reactive layer 16 and EBC 20 may be formed as a continuous layer, with reactive layer 16 including a relatively high phase composition of rare earth monosilicate and/or rare earth oxide, and EBC 20 having a relatively low phase composition of rare earth monosilicate and/or rare earth oxide.

As used herein, “formed on” and “on” mean a layer or coating that is formed on top of another layer or coating, and encompasses both a first layer or coating formed immediately adjacent a second layer or coating and a first layer or coating formed on top of a second layer or coating with one or more intermediate coatings or coatings present between the first and second layers or coatings. In contrast, “formed directly on” and “directly on” denote a layer or coating that is formed immediately adjacent another layer or coating, i.e., there are no additional intermediate coatings.

Various examples have been described. These and other examples are within the scope of the following claims.

1. An article, comprising:
substrate, wherein the substrate comprises at least one of a ceramic, a ceramic matrix composite (CMC), or a superalloy;
an intermediate coating on the substrate, wherein, when the intermediate coating is at an initial state, the intermediate coating comprises:
a bond coat on the substrate, wherein the bond coat comprises silicon; and
a reactive layer on the bond coat, wherein the reactive layer comprises a rare earth monosilicate or rare earth oxide; and
an environmental barrier coating (EBC) on the intermediate coating, wherein the EBC comprises a rare earth disilicate,
wherein, in response to oxidation of at least a portion of the silicon of the bond coat to form silicon dioxide, at least a portion of the rare earth monosilicate or rare earth oxide of the reactive layer is configured to react with at least a portion of the silicon dioxide to form a converted layer comprising a rare earth disilicate.

2. The article of claim 1, wherein the reactive layer has a thickness between about 10 microns and about 50 microns.

3. The article of claim 1, wherein a phase composition of the reactive layer comprises at least 50% of the rare earth monosilicate or rare earth oxide.

4. The article of claim 1, wherein a phase composition of the converted layer comprises at least 90% of the rare earth disilicate.

5. The article of claim 1, wherein a phase composition of the rare earth monosilicate or rare earth monosilicate in the reactive layer is greater than a phase composition of the rare earth monosilicate or rare earth monosilicate in the converted layer.

6. The article of claim 1, wherein the rare earth monosilicate or rare earth oxide of the reactive layer comprises ytterbium monosilicate or ytterbium oxide, wherein the rare earth disilicate of the converted layer comprises ytterbium disilicate, and wherein the silicon of the bond coat comprises silicon metal.

7. The article of claim 1, wherein,
when the intermediate coating is at the initial state, the intermediate coating comprises the bond coat at a first thickness, and
when the intermediate coating is at an operating state in which at least the portion of the silicon of the bond coat is oxidized, the intermediate coating comprises:
the bond coat at a second thickness, less than the first thickness;
a thermally-grown oxide (TGO) layer on the bond coat, wherein the TGO layer comprises the silicon dioxide; and
the converted layer on the TGO layer.

8. The article of claim 1, further comprising an abradable coating on the EBC.

9. A method of forming an article, comprising:
forming an intermediate coating on a substrate, wherein the substrate comprises at least one of a ceramic, a ceramic matrix composite (CMC), or a superalloy, and wherein the intermediate coating comprises:
a bond coat on the substrate, wherein the bond coat comprises silicon; and
a reactive layer on the bond coat, wherein the reactive layer comprises a rare earth monosilicate or rare earth oxide; and
forming an environmental barrier coating (EBC) on the reactive layer, wherein the EBC comprises a rare earth disilicate,
wherein, in response to oxidation of at least a portion of the silicon of the bond coat to form silicon dioxide, at least a portion of the rare earth monosilicate or rare earth oxide of the reactive layer is configured to react with at least a portion of the silicon dioxide to form a converted layer comprising a rare earth disilicate.

10. The method of claim 9, wherein, prior to oxidation of at least the portion of the silicon, the reactive layer has a thickness between about 10 microns and about 50 microns.

11. The method of claim 9, wherein a phase composition of the reactive layer comprises at least 40% of the rare earth monosilicate or rare earth oxide.

12. The method of claim 9, wherein a phase composition of the converted layer comprises at least 90% of the rare earth disilicate.

13. The method of claim 9, wherein a phase composition of the rare earth monosilicate or rare earth oxide in the reactive layer is greater than a phase composition of the rare earth monosilicate or rare earth oxide in the converted layer.

14. The method of claim 9, wherein the rare earth monosilicate or rare earth oxide of the reactive layer comprises ytterbium monosilicate or ytterbium oxide, wherein the rare earth disilicate of the converted layer comprises ytterbium disilicate, and wherein the silicon of the bond coat comprises silicon metal.

15. The method of claim 9, wherein forming the intermediate coating comprises:
depositing the bond coat on the substrate; and
depositing the reactive layer on the bond coat.

16. The method of claim 15, wherein the reactive layer is deposited to an initial thickness corresponding to a predetermined service life of the article in a high-temperature oxidative environment.

17. The method of claim 15, wherein the reactive layer is deposited with an initial phase composition corresponding to a predetermined service life of the article in a high-temperature oxidative environment.

18. The method of claim 9, further comprising forming an abradable coating on the EBC.

19. A method of operating an article, comprising:
exposing the article to a high temperature oxidative environment, wherein the article comprises:
a substrate, wherein the substrate comprises at least one of a ceramic, a ceramic matrix composite (CMC), or a superalloy;
an intermediate coating on the ceramic or CMC substrate, wherein the intermediate coating comprises:
a bond coat on the substrate, wherein the bond coat comprises silicon; and
a reactive layer on the bond coat, wherein the reactive layer comprises a rare earth monosilicate or rare earth oxide; and
an environmental barrier coating (EBC) on the intermediate coating, wherein the EBC comprises a rare earth disilicate,
wherein, in response to oxidation of at least a portion of the silicon of the bond coat to form silicon dioxide, at least a portion of the rare earth monosilicate or rare earth oxide of the reactive layer reacts with at least a portion of the silicon dioxide to form a converted layer comprising a rare earth disilicate.

20. The method of claim 19,
wherein the reactive layer has an initial thickness prior to exposure to the high temperature oxidative environment, and
wherein the article is exposed to the high temperature oxidative environment until an operating thickness of the reactive layer is less than about 80% of the initial thickness of the reactive layer.
